(19) United States
(12) Patent Application Publication
(10) Pub. No.: US 2010/0039237 A1
(43) Pub. Date: Feb. 18, 2010

(54) FRAMEWORK FOR FAST RFID TAG READING IN STATIC AND MOBILE ENVIRONMENTS

(76) Inventors: Sridhar Radhakrishnan, Norman, OK (US); Venkatesh Sarangan, Stillwater, OK (US); Malla Reddy Devarapalli, North Andover, MA (US)

Correspondence Address: DUNLAP CODDING, P.C., PO BOX 16370, OKLAHOMA CITY, OK, 73113, US

(21) Appl. No.: 12/492,902

(22) Filed: Jun. 26, 2009

Related U.S. Application Data
(60) Provisional application No. 61/075,790, filed on Jun. 26, 2008.

(51) Int. Cl. H04Q 5/22; H05K 13/00

(52) U.S. Cl. 340/10.4; 29/592.1

(57) ABSTRACT

An RFID reader for reading RFID tags is disclosed. The RFID reader is provided with a clock generating clock signals; a transceiver; a control unit receiving the clock signals; and a memory accessible by the control unit and storing computer executable instructions to cause the control unit to generate a communication schedule based upon confirmed reservation requests, and to read RFID tags employing the communication schedule. A RFID tag is also disclosed. The tag is provided with transmit/receive circuitry; a clock; a control unit; powering up circuitry including a power source; and memory storing an electronic product code (EPC). The memory also stores computer executable instructions that cause the control unit to receive a broadcast from a reader; synchronize the clock of the tag with the reader; generate and transmit a reservation request; receive a reservation summary including a reserved time to transmit; transmit the EPC; and receive an acknowledgement.

### CROSS-REFERENCE TO RELATED APPLICATIONS

The present application claims priority to U.S. Provisional Patent Application No. 61/075,790, filed on Jun. 26, 2008, the entire contents of which are incorporated herein by reference in its entirety.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of grants SAFETEA-LU 1934 and SAFETEA-LU 1702 awarded by the US Federal Highway Administration.

### THE NAMES OF THE PARTIES TO A JOINT RESEARCH AGREEMENT

The subject matter developed in the present application was made by or on behalf of parties to a joint research agreement that was in effect on or before the claimed invention was made. The claimed invention was made as a result of activities undertaken within the scope of the joint research agreement. The parties to the agreement are The Board of Regents of the University of Oklahoma and The Board of Regents of Oklahoma State University.

### BACKGROUND OF THE INVENTION

As background, RFID (Radio Frequency Identification) is an automatic identification scheme considered to be a better replacement of existing barcode technology. RFID possesses the advantages of contactless identification and the ability to hold more data with respect to barcode technology. RFID uses silicon chips or tags to store electronic product codes (EPC). The tags also have radio transceivers which transmit the EPCs to the devices that probe these tags. RFID has applications in a plethora of environments such as supply chain management, inventory control, supermarket checkout process, pet identification, and toll ways.

RFID tags can be categorized into different classes based on their functional characteristics [1]—(Engels et al., 2005): Class 0 and Class 1 (Identity Tags), Class 2 (Higher Functionality Tags), Class 3 (Semi-Passive Tags), Class 4 (Active Ad Hoc Tags), and Class 5 (Reader Tags). Out of these, tags belonging to classes 0, 1, and 5 find a wide spread usage. Class 0 and Class 1 tags are those that possess just the bare minimum functionality expected from a RFID tag, namely store and transmit functionality. Class 5 tags are those that have the ability to read the data stored in other classes of tags and are commonly referred to as readers.

Class 0 and Class 1 tags do not have any power source on their own and are usually powered by the readers through radio waves during the reading process. It is envisioned that the cost of these tags will come down to $0.05/unit [2]—(Sarma, 2001) over the next several years and the cost effectiveness of these tags will enable them to be used almost ubiquitously, thereby creating dense RFID environments. In order to completely tap into the potential benefits of the RFID technology, it is easy to infer that tag reading mechanisms which can read large number of tags efficiently within a short time are indispensable.

To achieve this goal of efficient tag reading, various tag reading protocols or RFID MAC protocols have been proposed in the literature. They are generally classified into two categories: deterministic and probabilistic [3]—(Avoine et al., 2005). Deterministic protocols are based on binary trees where each root-to-leaf path represents a unique tag id. Several of these protocols have been proposed for Class 0 Generation 1 tags [4]—(Myung et al., 2006), [5]—(Lee et al., 2000), [6]—(Zhou et al., 2004), [7]—(Namboodiri et al., 2007). Probabilistic protocols are based on the slotted ALOHA framework where the channel time is split into frames. A single frame in turn is divided into several time slots. During a frame, each tag randomly chooses a time slot and transmits its identifier to the reader in that slot. These protocols have been proposed for Class 1 Generation 1 tags. The inventive concepts recited in the present application generally focus on probabilistic protocols since deterministic protocols have a relatively long identification delay [8]—(Scharfeid, 2001), [9]—(Myung et al., 2006), [10]—(Myung et al., 2006), [11]—(Myung et al., 2006). Probabilistic tag reading protocols can achieve smaller identification delays provided the amount of time wasted due to collisions and idle time slots is reduced [12]—(Vogt, 2002). Generally, collisions occur when more than one tag transmits in the same slot, in which case all their identifiers are lost. Idle time slots occur when none of the tags in the reader's vicinity chose a particular slot for transmitting their identifier.

### BRIEF SUMMARY OF THE INVENTION

The present invention discloses a framework called Accelerated Frame Slotted ALOHA (AFSA) which reduces the duration of bit times wasted due to collisions and idle slots in probabilistic tag reading protocols. AFSA can be used in conjunction with any of the ALOHA based protocols to reduce the tag reading time. Discussed herein is the design and working of AFSA by taking the case of two different ALOHA protocols—Dynamic Framed Slotted ALOHA (DFSA) [13]—(Cha et al., 2006), a protocol with unlimited frame sizes and Extended Dynamic Framed Slotted ALOHA (EDFSA) [14]—(Lee et al., 2005), a protocol with limited frame sizes. Also disclosed are extensions of AFSA, with respect to both DFSA and EDFSA, to read tags in a mobile setting wherein the tags lie on a conveyor belt and pass through the readers fixed above the conveyor. Simulation results show that AFSA can reduce the average tag reading time by up to 40% with respect to the stand alone ALOHA protocols under both static and mobile settings.

Turning to general RFID protocols and related work in the field, almost all of the probabilistic tag reading protocols are based on slotted ALOHA. In these protocols, each tag reading round comprises of three phases. The first phase is the advertisement phase where the reader broadcasts the frame size to the tags. Frame size refers to the number of time slots available in a frame. The second phase is the transmission phase, during which each tag randomly chooses a time slot within the frame and transmits its EPC. If more than one tag chooses the same time slot, their transmissions collide and the slot will ultimately be wasted. A slot is also wasted when none of the tags chooses it for transmitting their EPCs. Only those slots that are chosen by exactly one tag each end up actually being used and such slots are also referred to as successful slots. The third phase is the acknowledgment phase, wherein the reader informs a tag if its transmission was successful. While the aforesaid working is common for all the probabilistic protocols, they differ in terms of the way in which they choose the frame size and the way in which they choose the tags that respond in a given round.

The basic frame slotted ALOHA (BFSA) [15]—(Finkenzeller, 2000) is the simplest of all the probabilistic protocols. It uses a fixed frame size for all the rounds, irrespective of the number of tags in the reader's vicinity. Consequently, the system efficiency drops significantly in case of both large and small tag counts. Under large tag counts, a lot of collisions occur while under small tag counts, many slots go unused. Dynamic Frame Slotted ALOHA (DFSA) overcomes this problem by dynamically changing the frame size as per the tag count. It gathers and uses information such as number of successful slots, idle slots, and collision slots from the previous round to determine the appropriate frame size for the next round.

Cha and Kim [13]—(Cha et al., 2006) propose another variant of DFSA which reduces the overall tag reading time by choosing a frame size that maximizes the probability of a slot being successful. In this variant, before each round, the number of unread tags in the system is first estimated by the reader. Using this estimated tag count, the frame size that maximizes the probability of a slot being successful is determined. This frame size is then used in the following round. ASAP [16]—(Khandelwal, 2005) is another protocol which similar to [13]—(Cha et al., 2006) in principle. However, ASAP uses slots of varying lengths and also a new tag estimation procedure. In ASAP, if a transmission slot is perceived to be idle, it is prematurely ended thus saving some time. The number of unread tags in the system is estimated using an expectation estimator and the frame size that maximizes the temporal efficiency for this tag count is then chosen. Temporal efficiency in ASAP is defined as the ratio of time actually spent in reading the tags over the wasted time.

Tree slotted ALOHA (TSA) [17]—(Bonuccelli et al., 2006) is a novel tag reading protocol which is a hybrid between slotted ALOHA and binary tree based tag reading techniques. The basic idea of TSA is to resolve a collision as soon as it happens. In Framed Slotted ALOHA protocols, two tags not colliding with each other in a given frame can collide in the next frame. TSA avoids this situation by making sure that when a collision occurs in a slot, only those tags that generated the collision in that slot are queried in the next read cycle. This results in a better performance.

While the above DFSA schemes perform well, they assume that the frame size can be increased indefinitely. However, in practice, it may not be possible to do so [18]—(Jain et al., 2006). In addition, large frame sizes can increase the interference between readers in a multi-reader environment. Consequently, schemes that can minimize the reading time with limited frame sizes are required. Enhanced Dynamic Frame Slotted ALOHA (EDFSA) [14]—(Lee et al., 2005) is one such scheme that guarantees a high tag reading rate even with a limited frame size. In EDFSA, under the assumption of equal slot durations, the frame size and the number of tags participating in a given round are chosen so as to maximize the probability of a slot being successful.

The framework described and illustrated in the present invention—Accelerated Frame Slotted ALOHA (AFSA)—decreases the amount of time wasted in ALOHA based tag reading protocols due to collisions and idle slots by employing bitmaps. AFSA thus brings down the overall time taken to read a tag. Described and illustrated herein is the design and working of AFSA, as used in the case of two different ALOHA protocols—the DFSA variant proposed in [13]—(Cha et al., 2006) (which assumes unlimited frame sizes) and Extended Dynamic Framed Slotted ALOHA (EDFSA) [14]—(Lee et al., 2005) (which assumes limited frame sizes). However, it should be understood that AFSA can be used in conjunction with any of the ALOHA based protocols to reduce the tag reading time. For ease of reference, hence forth, references to DFSA refer to the protocol proposed in [13]—(Cha et al., 2006). The following section provides a brief overview of DFSA and EDFSA.

A. DFSA

The working of DFSA [13]—(Cha et al., 2006) is the same as that of most other dynamic frame slotted ALOHA protocols. Each round in DFSA consists of three phases—advertisement, transmission, and acknowledgment. Let K be the actual number of unread tags present in the system. Before initiating the advertisement phase of a round, the reader estimates the value of K. An estimate, \hat{K}, is obtained by using the number of collisions observed by the reader in the previous round (Zc) and is given by \hat{K}=2.3922×Zc. Once the tag count has been estimated, the frame size (N) for the next ensuing round is chosen as N=\hat{K}. It can be shown that if K=\hat{K}, this choice of frame size indeed maximizes the probability of a slot being successful in the following round. The reader then advertises this seemingly optimal frame size to the tags. The transmission and acknowledgment phases then follow as described below.

B. EDFSA

As with DFSA, in EDFSA [14]—(Lee et al., 2005) too, the reader estimates the unread tag population in the beginning of each round. For determining \hat{K}, the estimation technique suggested by Vogt in [12]—(Vogt, 2002) is used. When the estimated tag population is small, the reader sets the frame size (N) according to the estimated population count as N=\hat{K}. For large estimated tag populations, the reader does not increase the frame size indefinitely as in DFSA. Instead, it restricts the number of tags that can participate in the following round so as to achieve better reading rates even with small frame sizes. After estimating the tag count, EDFSA divides the tag population into various groups. The number of groups M depends on the maximum frame size Nₘₐₓ and \hat{K} as M=[\hat{K}/Nₘₐₓ]

Once the reader determines the M value, it broadcasts this value along with the frame size to all the tags. The tags then generate a random number and carry out a modulo operation of this random number with the advertised group size. Tags with a zero remainder alone participate in that round and the rest of the tags stay muted. In other words, the grouping mechanism transforms a tag population which is too dense for the available frame size into a population which is approximately the optimum for the available frame size. All participating tags then generate a second random number in the range 1 to N to decide the slot number during which they should transmit their data. The transmission and acknowledgment phases then continue as in DFSA. In EDFSA, the frame sizes and the group numbers for different tag counts are estimated such that the probability of a slot being successful is maintained close to the maximum possible value of 36.8%. Assuming a maximum frame size of 256, FIG. 6 illustrates a list of the appropriate frame sizes and the number of groups for various unread tag populations [14]—(Lee et al., 2005).

The present invention is directed to an RFID system including a plurality of RFID tags and one or more readers. The RFID system reduces the average reading time of RFID tags (active or passive) in dense environments. The RFID system utilizes a computerized methodology termed Accelerated Frame Slotted ALOHA (AFSA) that can be used in conjunction with almost all RFID tag reading protocols that are based on frame slotted ALOHA. However, it should be understood that the present invention can also be used with other types of protocols such as a tree based protocol which is discussed in more detail below. It is shown that AFSA reduces the tag reading time by avoiding the wastage in bit times due to collisions and idle slots. The implementation of AFSA in conjunction with two different ALOHA protocols—one with unlimited frame sizes and the other with limited frame sizes is discussed by way of example herein. For both of these protocols, extensions of AFSA to read RFID tags in a mobile setting are also described. Simulation results show that AFSA reduces the average tag reading time by up to 40% with respect to the stand alone ALOHA protocols under both static and mobile settings.

AFSA decreases the amount of time wasted in ALOHA based tag reading protocols due to collisions and idle slots by having the tags generate a proposed reservation request (referred to as a parameter “n” below) and also by employing one or more communication schedules, which is referred to as a “bitmap” below, based upon accepted or confirmed reservation requests. An example of the communication schedule or “bitmap” is shown in FIG. 9. The communication schedule is a stored bit stream that indicates when particular RFID tags should transmit data to the reader.

It should be understood that certain embodiments are shown and described herein with reference to various parameters that can be varied depending upon the type of reader or tag utilized, or with respect to the environment in which the RFID system is designed to operate. For example, the reader is described as operating in either the 13.56 MHz or 860-900 MHz bands. However, it should be understood that the reader can be designed to operate in any appropriate band compatible with the reading of the tags. Further, the EPC is described, by way of example as being 64 bits in length. However, the length of the EPC can also be varied.

A framework for reducing the average reading time of RFID tags (passive or active) in dense environments is introduced. The proposed framework termed Accelerated Frame Slotted ALOHA (AFSA) can be used in conjunction with almost all RFID tag reading protocols that are based on frame slotted ALOHA. It is shown that AFSA reduces the tag reading time by avoiding the wastage in bit times due to collisions and idle slots. The implementation of AFSA in conjunction with two different ALOHA protocols—one with unlimited frame sizes and the other with limited frame sizes is discussed. For both these protocols, extensions of AFSA to read passive tags in a mobile setting are described. Simulation results show that AFSA reduces the average tag reading time by up to 40% with respect to the stand alone ALOHA protocols under both static and mobile settings.

It will be understood from the foregoing description that various modifications and changes may be made in the preferred and alternative embodiments of the present invention without departing from its true spirit. This description is intended for purposes of illustration only and should not be construed in a limiting sense. The scope of this invention should be determined only by the language of the claims that follow. The term “comprising” within the claims is intended to mean “including at least” such that the recited listing of elements in a claim are an open group. “A,” “an” and other singular terms are intended to include the plural forms thereof unless specifically excluded.

### BRIEF DESCRIPTION OF THE SEVERAL VIEWS OF THE DRAWINGS

FIG. 1 is an illustration of a framework for fast RFID tag reading in static and mobile environments constructed in accordance with the present invention.

FIG. 2 is a block diagram illustrating the exemplary components of an RFID tag constructed in accordance with the present invention.

FIG. 3 is a block diagram illustrating the exemplary components of a control unit of the RFID tag constructed in accordance with the present invention.

FIG. 4 is a flow diagram of a process for reading a RFID tag as used by the RFID tag as constructed in accordance with the present invention.

FIG. 5 is a table comparing the number of tags to the optimal frame size, as described by reference [14]—(Lee et al., 2005).

FIG. 6 is an illustration of the structure of an AFSA round as in a version of the present invention including an advertisement phase, a reservation phase, a summary phase, a transmission phase and an acknowledgement phase.

FIG. 7 is an illustration of the structure of the advertisement phase as used in a version of the present invention.

FIG. 8 is an illustration of the structure of the reservation phase as used in a version of the present invention.

FIG. 9 is an illustration of the structure of the reservation summary phase as used in a version of the present invention.

FIG. 10 is an illustration of the structure of the data transmission phase as used in a version of the present invention.

FIG. 11 is an illustration of the structure of the acknowledgement phase as used in a version of the present invention.

FIG. 12 is a chart showing absolute and approximate values of E[UC] for different n values with N=K.

FIG. 13 is an illustration of the structure of an m-AFSA round as used in a version of the present invention.

FIGS. 14a and 14b are charts showing simulated AFSA performance with different n values in accordance with the present invention, in particular, FIG. 14a illustrates the average simulated reading time obtained with different n values and FIG. 14b illustrates the average time lost in a round due to undetected collisions for different n values.

FIG. 15 is a chart showing the sample variation of n* values observed in one complete read.

FIGS. 16a-16c are charts showing simulated performance of different tag reading protocols in a static setting, in particular, FIG. 16a illustrates the average tag reading time obtained under ALOHA protocols, FIG. 16b illustrates the average tag reading time obtained under tree based protocols, and FIG. 16c illustrates the efficiency achieved by different protocols.

FIG. 17 is a table showing the simulated performance of AFSA and other protocols in a mobile setting.

### DETAILED DESCRIPTION OF THE INVENTION

Before explaining at least one embodiment of the invention in detail, it is to be understood that the invention is not limited in its application to the details of construction, experiments, exemplary data and/or the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

It should be understood that tag reading protocols can be collision based or non-collision based. The term collision or non-collision is used in the context when the tag sends its EPC (Electronics Product Code) number. Collision occurs when two or more tags send their EPC number to the reader at the same time. As with ALOHA based protocols the deterministic protocols such as tree protocols go in rounds to select the tag that has to send its EPC number. The number of rounds is dictated by the total number of tags that have information to send to the reader but it is bounded by the number of bits needed to represent the EPC number. For example at the beginning of the round, the reader will ask all tags that start with a 0 (in the bit representation of the EPC number) to send information. If there is more than one tag which starts with a 0, the reader will issue the bit string ‘1’ and continue along with ‘01’ and so on. After a few rounds the tags will have been appropriately grouped and now the reservation phase, reservation summary phase, transmission phase, and acknowledgement phase can be executed for each group separately, as discussed in more detail below. This illustrates that the present protocol can be embedded as part of other tag reading protocols to resolve collision(s) quickly and improve the tag reading rate.

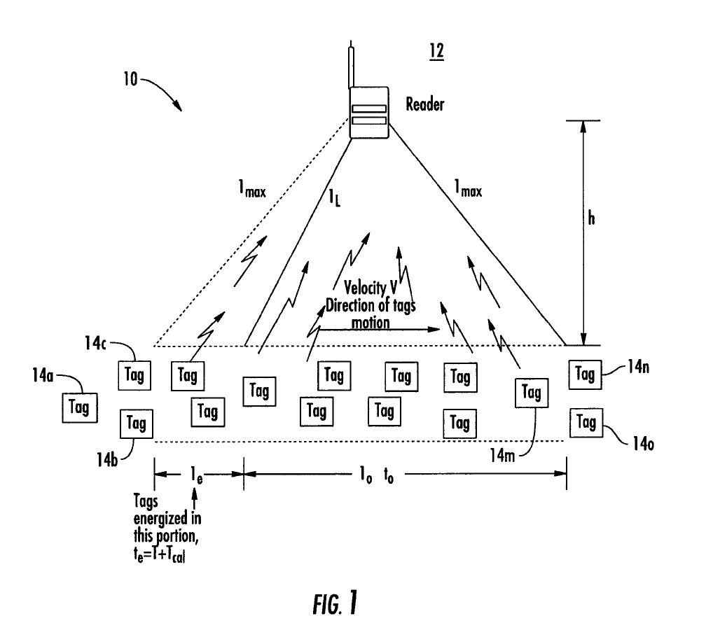

Referring to the drawings, and in particular to FIG. 1, shown therein and designated by reference numeral 10 is a RFID system 10 utilizing a framework for fast RFID tag reading in static and mobile environments constructed in accordance with the present invention. The RFID system 10 includes at least one reader 12 and a plurality of RFID tags 14 (illustrated by reference numerals 14a-14o, only 6 of which are labeled). Although 15 RFID tags 14 are shown therein, it should be understood that the RFID system 10 can be comprised of any number of RFID tags 14.

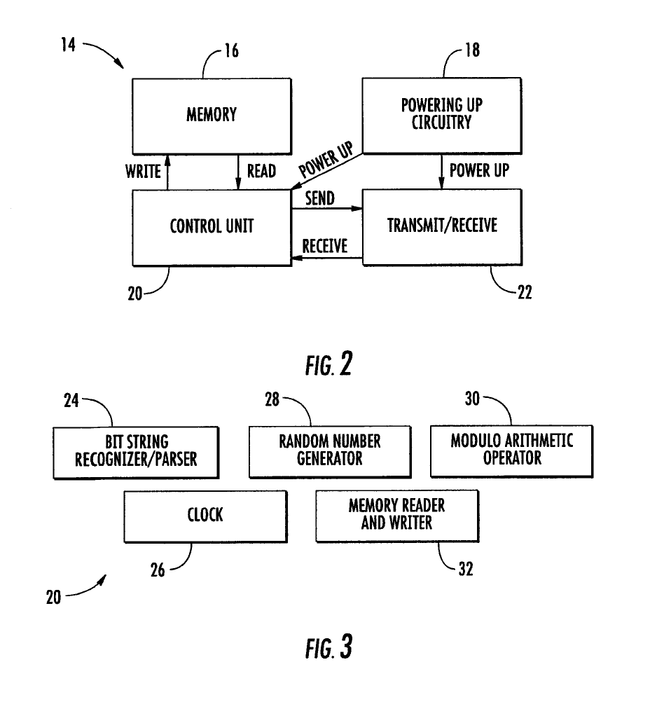

Shown in FIGS. 2 and 3 are block diagrams of an exemplary RFID tag 14 and an exemplary functional diagram of a control unit 20 of the RFID tag 14 which are constructed in accordance with the present invention. The RFID tag 14 is provided with a memory 16, a powering up circuitry 18, a control unit 20, and a transmit/receive unit 22. The powering up circuitry 18 provides the power needed for all the other units to operate. The power source of the powering up circuitry 18 can be either an AC/DC source (which is a feature of active RFID tags) or power harvested from RF waves from the RFID reader system 10 (which is a feature of the passive RFID tags). Upon powering up, the transmit/receive unit 22 is responsible for converting the modulation and demodulation functions. The RF signal received by the transmit/receive unit 22 is demodulated into a bit string which is passed on to the control unit 20. The bit string sent by the control unit 20 is modulated into a RF wave by the transmit/receive unit 22. The control unit 20 is programmed with suitable logic to recognize the bit string, start a clock, start a timer, reset a timer, generate one or more random number(s), perform modulo arithmetic, perform arithmetic comparisons, and read and write to memory 16. The control unit 20 can be implemented utilizing one or more processing device which can be embedded on the RFID tags, such as one or more microcontroller(s), one or more microprocessor(s), one or more digital signal processor(s), or one or more field programmable gate array. Logic in the form of software instructions or hardware for performing the AFSA functions described herein is stored in a computer readable medium, such as the memory 16 and is typically accessed by the control unit 20 to perform the AFSA functions described herein. For example, there are systems which can etch the circuitry directly on the tag capable of performing the desired functions.

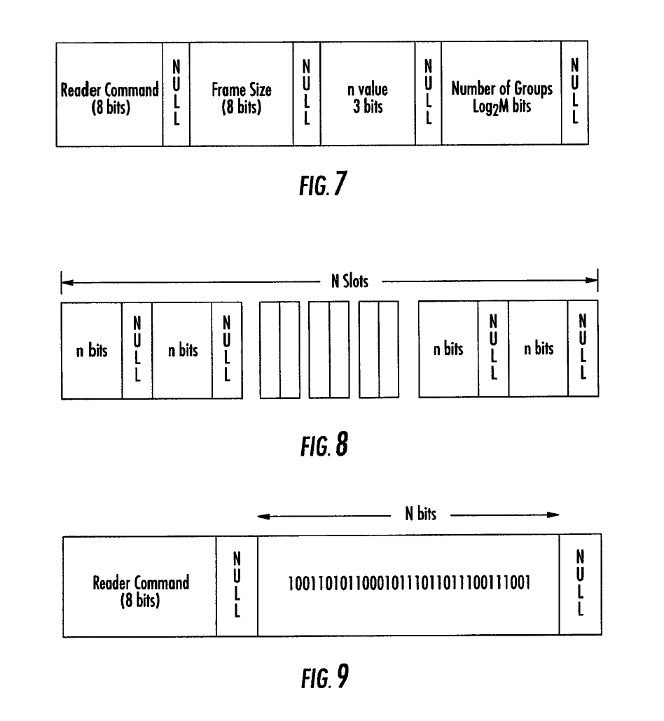

The control unit 20 of the RFID tag 14 is typically programmed to provide a bit string recognizer/parser unit 24, a clock 26, a random number generator 28, a modulo arithmetic operator 30, and a memory reader and writer 32. The Bit String Recognizer/Parser unit 24 is responsible for recognizing the input from the reader 12. For example the reader 12 can start the Advertisement Phase (see FIG. 7) by broadcasting two numbers along with the prefix bit string indicating that it is the advertisement phase. The RFID tag 14 should parse the bit string and recognize it is indeed in the Advertisement Phase and perform appropriate functions as specified in the AFSA protocol. It is also needed as part of the reservation summary phase (see FIG. 9), wherein each RFID tag 14 checks if the reserved time slot is available for them. This requires for each RFID tag 14 to, first recognize that the reservation summary phase is based on a prefix bit string sent from the reader 12, and second to check if a bit string sent from the reader 12 has a bit of ‘1’ in a particular position. The clock 26 is turned on when the control unit 20 is turned on by the powering up circuitry 18. A timer is part of the clock 26 which can be started and stopped at specified intervals of time. This is useful for recognizing the beginning and end of time slots. The functions of the other units are straight forward to understand as they are part of the protocol implementation.

The RFID tag 14 or the reader 12 can be provided with any suitable processing device capable of performing the functions described herein, such as a microprocessor, digital signal processor, field programmable gate array or a microcontroller. Most RFID tags 14 that are commercially available have a microcontroller capable of performing the above described functions.

Turning now to the proposed AFSA framework—system model. Generation 1 RFID systems work either in the 13.56 MHz ISM band or 900 MHz UHF band, while Generation 2 systems can work in the 860 MHz-960 MHz UHF band. Described herein is a collision limited 900 MHz UHF RFID system where the tags communicate with the reader over a shared channel. [16]—(Khandelwal, 2005), [19]—(Khandelwal et al., 2006) have considered such a system and shown that the received SNR is high enough to justify this assumption when passive tags are communicating over a short range. However, it should be understood that the proposed AFSA framework can be adapted for RFID systems that work in the 13.56 MHz or 860-960 MHz bands too by appropriately changing the slot timing values in the design expressions.

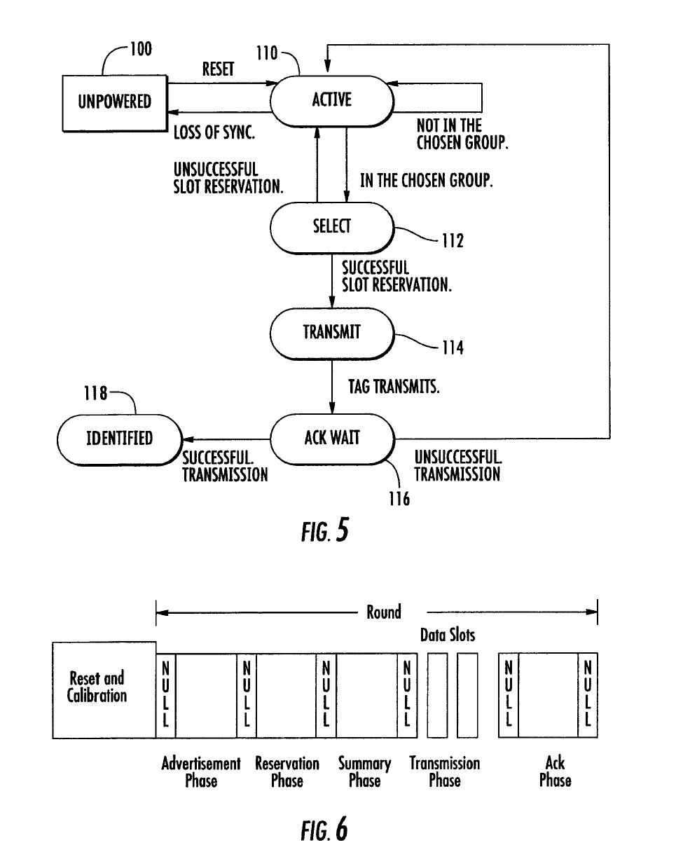

In the RFID system 10 described herein, the reader 12 uses a 900 MHz continuous wave to power the RFID tags 14. Each RFID tag 14 transmits its EPC (which is assumed to be 64 bits) along with a 16 bit CRC (cyclic redundancy check code) with a symbol duration of 4 μS [20]—(2003). RFID tags 14 employ FSK (Frequency Shift Keying) backscatter modulation to transmit their data. Reader 12 uses the symbols ‘0’, ‘1’, and ‘Null’ to communicate with the tags. The symbols ‘0’ and ‘1’ are used for constructing commands while the ‘Null’ symbol is used for marking the beginning of a command, the end of a command, and the end of a slot within a frame. The duration of these symbols is 12.5 μS [20]—(2003). Reader 12 communicates with RFID tags 14 in ‘rounds’ whose structure is shown in FIG. 6 for example.

A flow diagram of the logic of an RFID tag state machine under AFSA is illustrated with reference to FIG. 4 and described below. The process will be described with passive tags. However, it should be understood that such process is equally applicable to active tags with the exception of the unpowered state. To begin with, all the RFID tags 14 are in an unpowered or passive state 100. The reader 12 sends the reset, oscillator calibration, and data symbol calibration signals listening to which the RIFD tags 14 move to the active state 110. The reader 12 then advertises the group size and the frame size to the RFID tags 14. If the advertised group size is 1, all RFID tags 14 move to the select state 112. If the advertised group size is greater than 1, the RFID tags 14 carry out a modulo operation as described below. RFID tags 14 that have a remainder zero move to the select state 112 while other RFID tags 14 remain in the active state 110. RFID tags 14 in the select state 112 exchange a few bits of information with the reader 12. For example, the reader 12 can exchange three bits of information in order to advertise n to the RFID tags 14. After this exchange, some of the RFID tags 14 in the select state 112 transit to the transmit state 114 while the remaining RFID tags 14 go back to the active state 110. In the transmit state 114, the RFID tags 14 send their EPC codes to the reader 12. If a RFID tag's 14 transmission is successful, it goes to the identified state 118 and if not, it goes back to the active state 110.

The proposed AFSA framework has five phases to complete a single round of tag reading. The overall structure of a round of operation under AFSA is shown in FIG. 6 and the individual phases are described below.

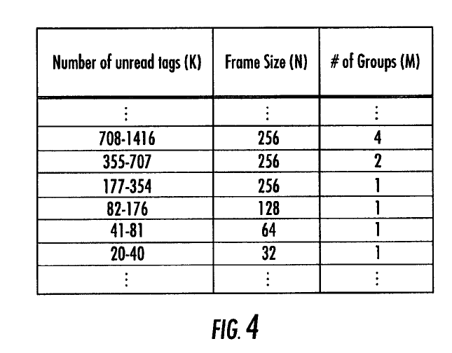

(1) Advertisement Phase (see structure shown in FIG. 7). During this phase, the reader 12 broadcasts the frame size (N) and the number of groups (M) to all the RFID tags 14 that are within its range. The parameters N and M are decided by the underlying ALOHA protocol (for example, the ALOHA protocol can be either DFSA or EDFSA). In the case of DFSA, the protocol assumes the frame size to be unlimited and does not follow any grouping. Therefore, the value of M is set to 1. The value of N value is set to \hat{K}, the estimated number of unread RFID tags 14 in the reader's 12 vicinity. In the case of EDFSA, the values for N and M are chosen as per the table shown in FIG. 5 by approximating K with \hat{K}. In addition to M and N, the reader 12 also advertises n (a reservation request), which is a parameter introduced by the AFSA framework and will be discussed in more detail below.

Once the values of N and M are known, the RFID tags 14 first determine their eligibility to participate in the ensuing round. If M=1, all RFID tags 14 are allowed to participate and if M>1, each RFID tag 14 determines its eligibility as per the methodology described herein. Each eligible RFID tag 14 transits to the select state 112 and generates another random number which is uniformly distributed in the range of 1 to N. This number identifies the slot that the RFID tag 14 has chosen to transmit its data.

(2) Reservation Phase (see structure shown in FIG. 8). In this phase, the RFID tags 14 in the select state 112 let the reader 12 know about the slots that they have chosen. Unlike other slotted ALOHA protocols where the RFID tags 14 send their data right away in the chosen slot, in AFSA the RFID tags 14 transmit an n bit sequence in their chosen slot, where n is the number advertised by the reader in the advertisement phase. For a given value of n, there are 2ⁿ possible n bit sequences. A RFID tag 14 randomly picks one of these 2ⁿ sequences and transmits it to the reader 12 in the slot chosen by it. If the reader 12 successfully receives an n bit sequence in a slot, it perceives that slot to be successfully reserved by some RFID tag 14 for transmitting its data. On the other hand, if the reader 12 receives a garbled signal in a slot it understands that a collision has occurred between two or more RFID tags 14 in that slot.

(3) Reservation Summary Phase (see structure shown in FIG. 9). During this phase, the reader 12 informs the RFID tags 14 about the status of their slot reservations. The reservation status is advertised through a bitmap of length N. For example, assuming N=4, the bitmap 1001 indicates that an n bit sequence was successfully received by the reader 12 in the slots numbered 1 and 4. This implies that, those RFID tags 14 that had chosen slots 1 and 4 were successful in their reservation. In other words, occurrence of bit 1 in location i indicates that only one RFID tag 14 had chosen slot i. During slots 2 and 3, the reader 12 did not successfully receive any n bit sequence. This can indicate one of the two possibilities: (i) collisions—these slots were chosen by more than one RFID tag 14 and when the tags transmitted their randomly chosen n bit sequences, collision occurred and consequently, the reader 12 was not able to decode the received signal; or (ii) idle—the slots were not chosen by any of the RFID tags. In other words, occurrence of bit 0 in location i indicate that slot i has been wasted either due to collisions or idleness.

(4) Data Transmission Phase (see structure shown in FIG. 10). After the reservation summary phase, all the participating RFID tags 14 will be aware of the status of their reservations. Only those RFID tags 14 that find their reservations to be successful will move to the transmit state 114 and will transmit their data in the data transmission phase. The remaining RFID tags 14 will go back to the active state 110. Note that if S is the total number of ‘1’s in the summary bitmap, it is clear that only S data transmissions are possible, where S≦N. Hence, it is enough if there are just S data transmission slots. A RFID tag 14 that finds a ‘1’ in the summary bitmap in the location corresponding to its chosen slot (say i) can easily determine its turn in the sequence of S transmissions by counting the number of ‘1’s in the summary bitmap starting from location one until location i. For example, if the summary bitmap is 1001, the RFID tag 14 that had reserved the fourth slot in the reservation phase should transmit second in the data transmission phase.

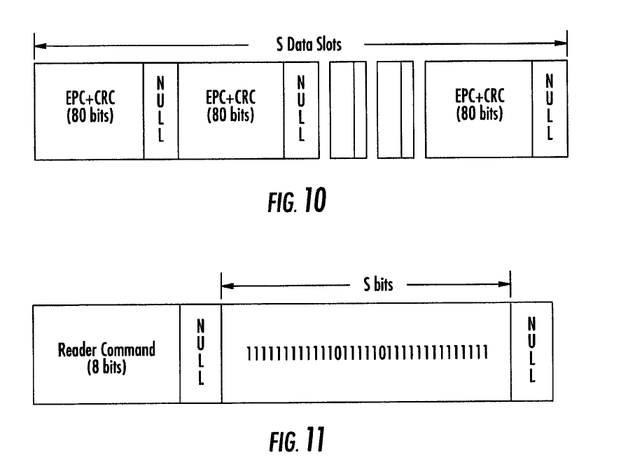

(5) Acknowledgment phase (see structure shown in FIG. 11). This is the final phase in which the reader 12 acknowledges the data transmitted by the RFID tags 14. The acknowledgment is sent in the form of bits—a ‘1’ indicates that the transmission in that corresponding slot was received successfully and a ‘0’ indicates that the transmission was not successful. All RFID tags 14 that received a positive acknowledgment from the reader will transit to the identified state 118 and become muted. Such RFID tags 14 will not participate further in the tag reading process. RFID tags 14 that received a negative acknowledgment will go back to the active state 110 and will participate in the reading process again.

Duration of a round: let T denote the total duration of a round. Let T_{Ad}, T_{R}, Tₛᵤ, T_{D}, and T_{Ack} respectively denote the durations of the advertisement, reservation, summary, data transmission, and the acknowledgment phases. Now, T can be written as:

T=T_{Ad}+T_{R}+T_{Su}+T_{D}+T_{Ack} (1)

From the system model, it is clear that when the EPC is transmitted along with the CRC, the symbol duration is 4 μS. For all other transmissions, the symbol duration is 12.5 μS. Therefore, we can express Let T_{Ad}, T_{R}, Tₛᵤ, T_{D}, and T_{Ack} as follows (all in μS):

T_{Ad}=12.5×(20+log 2M+3)

T_{R}=12.5×N(n+1)

T_{Su}=12.5×(10+N) (2)

T_{D}=S×80×4+12.5×S

T_{Ack}=12.5×(10+S)

In the AFSA framework, the total number of information bits that are exchanged between the reader 12 and the RFID tags 14 is Nₙ+N+64S. In the original protocols (DFSA or EDFSA), 64N number of bits are exchanged between the reader 12 and the RFID tags 14. Since S≦N, by choosing n<<64, the total number of bits exchanged during a single round in AFSA can be made smaller than that of the base protocols. This in turn can lead to quicker rounds and smaller tag reading times.

C. Tag Estimation

In order to advertise the appropriate frame size (N) and the group number (M), the reader 12 has to arrive at \hat{K}—an estimate on the actual number of tags K that need to be read. Several tag estimation strategies have been proposed by researchers in [12]—(Vogt, 2002), [13]—(Cha et al., 2006), [19]—(Khandelwal et al., 2006), [21]—(Murali et al., 2006) and any of them can be used. The strategy suggested in [19]—(Khandelwal et al., 2006) is described herein on account of its simplicity and adequate accuracy. However, it would be understood that other estimation strategies can be used in the present invention without departing from the inventive aspects recited herein. For the sake of completeness, the tag estimation strategy is reproduced herein below.

Let E[I] be the expected number of idle slots when the frame size is N and the participating RFID tag 14 count is K. It is possible to express E[I] as E[I]=N(1−1/N)^{K}. Let Z_{I} be the total number of idle slots observed by the reader 12 in a given round. Then by approximating E[I] with Z_{I}, we can estimate the number of RFID tags 14 that would have participated in that round as:

$${\hat{K}}_{Ex p} = \frac{log ( \frac{{Z}_{I}}{N} )}{log ( 1 - \frac{1}{N} )} \qquad ( 3 )$$

The number of RFID tags 14 that will participate in the next round can be arrived as R_{Exp}-Z_{S}, where Z_{S} to the number of successful slots observed in that round. In cases where no idle slots have been observed, i.e., Z_{I}=0, the tag count is estimated to be the lower bound of Z_{S}+2Z_{U} where Z_{U} refers to the number of collision slots observed in a given round.

It is to be noted that if the underlying protocol dictates that the group count M be greater than 1, then only a fraction of the unread RFID tags 14 would have participated in a round. Therefore, in such a scenario, an estimate on the actual number of unread RFID tags 14 can be arrived at by multiplying the estimated tag count [symbol] with the number of groups M.

### AFSA Optimization

In the discussions above, it was mentioned that during the reservation phase, each RFID tag 14 transmits a randomly chosen n bit sequence in the slot selected by it. If more than one RFID tag 14 chooses the same slot, a collision occurs. The reader 12 can detect this collision only if the bit sequences transmitted by the RFID tags 14 that chose the same slot are different. However, if all the RFID tags 14 that chose the same slot transmit the same n bit sequence, the reader 12 cannot detect the collision occurring in that slot. The consequence of a collision going undetected is that the reader 12 may wrongly interpret a slot reservation to be successful when in reality, it is not. This incorrect interpretation will lead to collisions in the data transmission phase. In other words, undetected collisions will increase the number of bits wasted in a round which in turn increases the round time and thereby the overall tag reading time.

The probability of a collision going undetected depends on two factors—a) the probability of more than one tag choosing the same slot and (b) the probability of all the tags that chose the same slot selecting the same n bit sequence. The former is decided by the value of frame length N and the number of tags K competing for the slots, while the latter is decided by the value of the parameter n. Since the values of N and K are decided by the underlying protocol, AFSA has no control over them. The only parameter that can be varied to reduce the number of undetected collisions is n, the length of the bit sequence used by the tags to reserve their slots.

Intuitively, it is clear that by opting for a large value for n, the number of undetected collisions can be decreased. However, increasing the value of n also implies that the RFID tags 14 have to transmit more number of bits in the reservation phase, thereby increasing the round time and overall tag reading time. Thus both smaller and larger values of n increase the overall round time. We now describe how to determine the optimal value n* that minimizes the total round time for given values of N and K. A closer look at the different phases of the proposed framework will reveal that, the value of n significantly affects the durations of the reservation, data transmission, and acknowledgment phases alone. Once the durations of these phases are known in terms of n, n*can be determined by differentiating their sum with respect to n and equating the outcome to zero. We now reproduce the expressions for T_{R}, T_{D}, and T_{Ack} below:

T_{R}=N(12.5n+12.5)

T_{D}=S(80×4+12.5) (4)

T_{Ack}=(10+S)×12.5

The parameter S represents the total number of successful slot reservations as perceived by the reader 12 in the reservation phase. It is possible to write S as follows:

S=E[R]+E[UC] (5)

where E[R] represents the average number of slots that were truly reserved (i.e., these are the total number of slots that were each selected by exactly one RFID tag 14) and E[UC] represents the average number of collision slots that were undetected by the reader 12. Since the RFID tags 14 choose one among the N slots as per a uniform distribution, the value for E[R] can be written as [14]—(Lee et al., 2005):

$$E [ R ] = {K ( 1 - \frac{1}{N} )}^{K - 1} \qquad ( 6 )$$

A collision goes undetected when more than one RFID tag 14 chooses the same slot and all the tags corresponding to a given slot select the same n bit sequence. Let X(i) be the expected number of slots that have been selected by exactly i tags. X(i) can be written as

$$X ( i ) = N ( \frac{K}{i} ) {( \frac{1}{N} )}^{i } {( 1 - \frac{1}{N} )}^{K - i} .$$

Since the slot selection and the n-bit sequence selection are independent of each other, the expected number of undetected collisions that may happen in slots with tag occupancy i can be written as: E[UC|occupancy=i]=X(i) Pᵢ, where Pᵢ is the probability that all the i tags in a slot choose the same n bit sequence and is given by

$${P}_{i} = \frac{1}{{2}^{n ( i - 1 )}} .$$

Now the expected number of undetected collisions that may happen in all the N slots can be written as:

E[UC]=Σᵢ₌₂^{K-E[R]}X(i)pᵢ (7)

While the above expression gives the accurate value of E[UC], it becomes a little cumbersome to handle when we attempt to find n*. We derive an alternate, simpler expression that gives an approximate value of E[UC] and use this expression to determine n*. Let E[U] represent the total number of slots that were chosen by more than one RFID tag 14. The value for E[U] is given by:

E[U]=N−E[I]−E[R] (8)

where E[I] refers to the total number of slots that were not chosen by any of the RFID tags 14 (idle slots). Given that each tag independently selects any particular slot with equal probability, E[I] can be written as

$$E [ I ] = {N ( 1 - \frac{1}{N} )}^{K}$$

[13]—(Cha et al., 2006). It is easy to observe that if the reader 12 fails to detect a collision in a particular slot, then that slot should be one of the E[U] slots. Also by definition, each of the E[U] slots is chosen by at least two tags (possibly more). Therefore, if P₂ represents the probability of two tags selecting the same n bit sequence in the reservation phase, then E[UC] can be written as:

E[UC]≦E[U]P₂ (9)

It can also be noted that P₂ is equal to ½ⁿ. We use the above upper bound to approximate E[UC] in our n* estimation. Combining the above, and minimizing the sum of T_{R}, T_{D}, and T_{Ack} with respect to n gives us n* which can be written as:

$${n}^{*} = 3.32 {log}_{10} ( \frac{19.14 E [ U ]}{N} ) \qquad ( 10 )$$

Using the above value of n* in the protocol minimizes the total round time for given values of N and K.

Remarks on the approximation: As mentioned above, for analytical tractability, the actual value of E[UC] is approximated with an upper bound. In order to get some perspective on the tightness of this bound, the actual values of E[UC] and the upper bound used for approximation are shown in FIG. 12. In obtaining these values, the relation N=K was followed, since this is the optimal frame size for ALOHA based tag reading protocols with equal slot sizes. From FIG. 12, the approximation used introduces an error of roughly 35%. Since we approximate E[UC] by an upper bound, the resulting value of n* will be conservative, i.e., it will be greater than or equal to the true value of n*. In spite of using this conservative n* value, it has been found that the performance of the AFSA framework is still better than that of standalone ALOHA protocols.

m-AFSA: AFSA for Mobile Environments

One of the biggest challenges facing RFID tag reading protocols is to read the tags effectively and efficiently when the RFID tags 14 are mobile and are passing through the readers' 12 range as in the case of assembly lines. The challenge arises out of the fact that in a mobile setting, the reader 12 has a limited time to complete the reading process. The RFID tags 12 get muted or killed not only after a successful read but also when they leave the reader's 12 field, whichever occurs first. The focus of the following discussion is to extend the proposed AFSA framework to a mobile setting and design the initial RFID tag population, tag arrival and departure rates such that a desired tag reading probability is guaranteed.

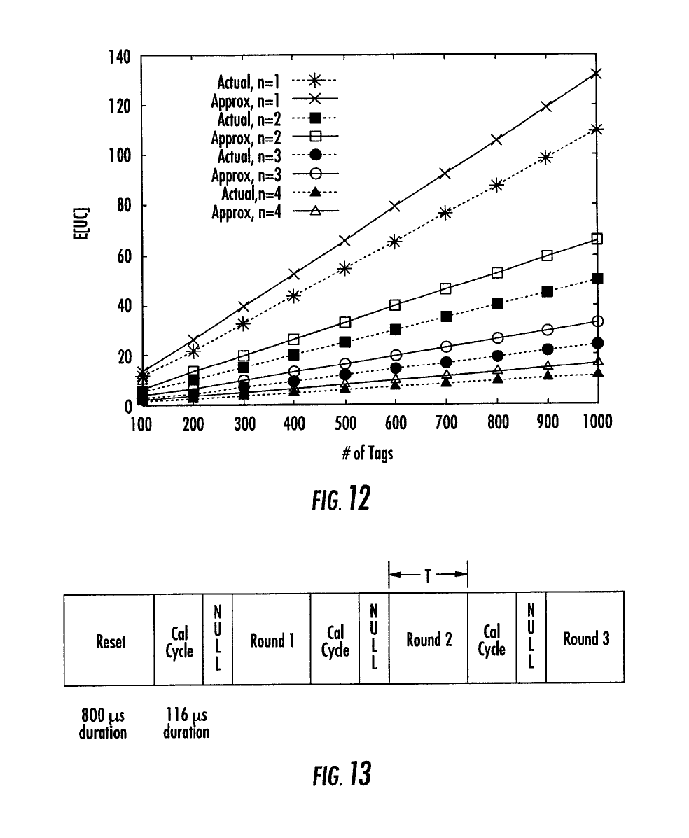

For simplicity purposes, the m-AFSA system is adopted similar to the one used in [19]—(Khandelwal et al., 2006). That is, we consider a 900 MHz RFID system in which the RFID tags 14 arrive into the reader 12 region on a conveyor belt moving with a constant velocity v. In stationary RFID systems, the reader 12 calibrates and synchronizes the RFID tags 14 only at the beginning of the identification process. In mobile RFID systems, since new RFID tags 14 may continuously enter the reader's field, the reader 12 should be able to accommodate intermediate tag calibration and synchronization. In order to achieve this, at the beginning of each round, the reader 12 transmits the ‘oscillator calibration’ signal to synchronize the newly arrived RFID tags 14. The round structure adopted in m-AFSA is shown in FIG. 13 and the system set up is shown in FIG. 1.

The reader 12 is located at a height of h meters above the conveyor belt on which the RFID tags 14 arrive. The reader 12 is assumed to be capable of communicating with a RFID tag 14 as long as the distance between the tag 14 and the reader 12 is less than lₘₐₓ, the maximum operating range of the reader 12. The RFID tags 14 spend a total time of t=tₑ+tₒ in the reader's 12 vicinity where, tₑ is the time duration during which RFID tags 14 get energized and synchronized and tₒ is the operating time available for the RFID tags 14 to transmit their data before they leave the reader's 12 field. It is easy to see that

$$= \frac{\sqrt[2]{{l}_{ma x}^{2} - {h}^{2}}}{v} .$$

As in [19]—(Khandelwal et al., 2006), we choose tₑ=T+T_{cal}+T_{Null} to guarantee that each new batch of RFID tags 14 get at least one calibration cycle before they can transmit their data. As before, T refers to the duration of a round. Let q denote the number of rounds a RFID tag 14 can participate in the reading process when it is passing through the reader's 12 range. It is easy to observe that:

$$\begin{matrix}q = ⌊ \frac{{t}_{o}}{T + {T}_{Cal} + {T}_{Null}} ⌋ \\ = ⌊ \frac{t}{T + {T}_{Cal} + {T}_{Null}} ⌋ - 1\end{matrix} \qquad ( 11 )$$

Let P be the RFID tag 14 reading rate that is desired. If pᵣ is the average probability of a RFID tag 14 being read in a given round, it is clear that pᵣ should satisfy the following condition:

(1−pᵣ)^{q}≦1−P (12)

We denote the group of RFID tags 14 that enter the reader's field at the beginning of round i as group Gᵢ tags. Let φ be the arrival rate of the RFID tags 14. Since the RFID tags 14 are moving on a conveyor with constant velocity, the tag arrival rate is equal to the tag departure rate.

Under this set up, to complete the design of m-AFSA, we need to find Gᵢ, pᵣ T, and φ such that Equations 11 and 12 are satisfied. The design of m-AFSA is influenced by the base protocol under consideration. m-AFSA design is notably different for DFSA and EDFSA owing to the philosophical difference (in terms of using limited and unlimited frame sizes) in the base protocols themselves. In the following paragraphs, we delineate the design of m-AFSA for DFSA and EDFSA.

A. m-AFSA for DFSA

In DFSA, the number of RFID tags 14 participating in a round Gᵢ, influences the round duration T. On the surface, it may seem that Gᵢ, can affect the value of pᵣ too. However, as the following arguments show, the success probability pᵣ remains unaffected by Gᵢ. This is because, in DFSA, under ideal conditions, the frame size Nᵢ, in a given round i is always chosen such that Nᵢ=Gᵢ. With this relation, the expected number of RFID tags 14 to be successfully read in a round is given by:

$$\begin{matrix}{SG}_{i} = {{G}_{i} ( 1 - \frac{1}{{G}_{i}} )}^{{G}_{i} - 1} \\ \approx {G}_{i} {e}^{- 1} ( for large values of {G}_{i} ) \\ = 0.368 {G}_{i}\end{matrix} \qquad ( 13 )$$

Thus we can arrive at pᵣ=0.368, which is independent of Gᵢ. Having determined pᵣ, the number of rounds required to meet the desired read percentage can be found from Equation 12 as:

$$q = ⌈ \frac{log ( 1 - P )}{log ( 1 - {p}_{r} )} ⌉ \qquad ( 14 )$$

From q and Equation 11, the duration available for a single reading cycle T can be derived as:

$$T = \frac{t}{q + 1} - {T}_{Cal} - {T}_{Null} \qquad ( 15 )$$

Let G₁ denote the number of RFID tags 14 participating in round 1. It is clear that at the end of round 1, 0.368G₁ tags will be successfully read by the reader 12. The key in m-AFSA is to keep the number of unread tags in each round to be approximately the same at G₁, i.e., Gᵢ=G₁ for all i. Since 0.368G₁ tags are read on an average in round 1, the number of new tags that enter the reader's field in round 2 is set to 0.368G₁, i.e., φ(T+T_{cal}+T_{Null})=0.368G₁ from which φ can be determined. This also means that 0.368G₁ tags leave the reader's field at the end of every round. All that remains now is to determine the G₁ value which will satisfy the T obtained above in Equation 15.

Estimating G₁: For convenience, we re-state Equation 1 that defines T here:

$$\begin{matrix}T = {T}_{Ad} + {T}_{R} + {T}_{Su} + {T}_{D} + {T}_{Ack} \\ = ( 20 + {log}_{2} M + 3 ) * 12.5 + N ( n + 1 ) * 12.5 + ( 10 + N ) * \\ 12.5 + S * 80 * 4 + S * 12.5 + ( 10 + S ) * 12.5\end{matrix} \qquad ( 16 )$$

We now proceed to express (recalling that in DFSA, the number of groups M=1) N, n, and S in terms of G₁. Since the frame size is always equal to the number of RFID tags 14, N=G₁. In AFSA, we always use the optimal value of n given in Equation 10. By substituting N=G₁ and K=G₁ in this expression and through simple algebra, we can arrive at the result n*=2, i.e., when N=K=G₁, the optimal value for n is a constant and equals 2. Using this result and from Equations 5, 6, 8, and 9, we can arrive the following:

S=E[R]+E[U].P₂=0.434G₁ (17)

Having expressed N, n, and S in terms of G₁, we can now write T (in μs) given in Equation 16 as

T=537.5+199.73G₁ (18)

from which G₁ can be determined.

Recall that to complete the design of m-AFSA with DFSA as the underlying protocol, parameters Gᵢ, pᵣ, T, and φ have to be determined such that Equations 11 and 12 are satisfied. It is clear that the above discussions precisely enable us to achieve this. Therefore, the design of m-AFSA with DFSA as the underlying protocol is complete.

B. m-AFSA for EDFSA

In EDFSA, on account of assuming an upper bound on the frame size, the number of RFID tags 14 participating in a round Gᵢ, not only affects the round time T but also the success probability, pᵣ. In designing m-AFSA for EDFSA, we severe the dependency of T on Gᵢ by using a conservative value for T. The T value chosen is conservative in the sense it minimizes q, the number of rounds in which a RFID tag 14 can participate. Once a conservative value of q is estimated, we determine the Gᵢ values such that the resulting probability pᵣ satisfies Equation 12. This will complete the design of m-AFSA for EDFSA.

A conservative estimate for q: As Equation 11 shows, q depends on t and T. The value of t is determined by the system architecture, while T depends on N, K, and n. The actual value of N (the number of reservation slots) is determined by the number of unread tags K that are present within the reader's range. Since we use EDFSA as the base protocol, the N value varies as shown in Table I illustrated in FIG. 5. In a mobile setting, as there is a continuous stream of unread RFID tags 14 arriving into the system, it is advantageous to set N at the maximum possible value so as to increase the system throughput. This implies that N can be fixed at 256. With N set at 256, the value of T can be determined if the parameter S is known. The value of S depends on K and n*. The value of n* used in AFSA is actually dynamic and it varies as per the value of K. To simplify the design, we approximate n* by the constant 2 and as the simulation results reveal, it turns out that this is a reasonable approximation in terms of the overall tag reading time. With N and n*. fixed, S now depends only on K, the number of unread RFID tags 14 in the population. The value of K is chosen to be the one that maximizes S. Maximizing S will maximize T and therefore will minimize q. For N=256, and n*=2, we find that K=336 maximizes S and hence this K is used to estimate T. With afore said parameters, the maximum value of T is estimated to be 52.92 ms using which a conservative estimate for q can be arrived at.

Estimating Gᵢ: Having estimated a conservative value for q, all that remains to be estimated are the Gᵢ values. Let G₁ denote the number of RFID tags 14 participating in round 1 and SG₁ represent the number of RFID tags 14 that are successfully read in round 1. As per the EDFSA grouping statistics presented in the Table shown in FIG. 5, when N=256, the optimal number of RFID tags 14 that can participate in the reading process is between 177 and 354. Following the same principle in the present disclosure, set 176≦G₁≦354. Under these conditions, it can be shown easily that 88≦SG₁≦94 and that the average value of SG₁ is 92. The key in m-AFSA is to keep the number of unread RFID tags 14 in each round to be approximately the same at G₁, i.e., Gᵢ=G₁ for all i. Since 92 RFID tags 14 are read on an average in a round, the number of new RFID tags 14 that enter the reader's field in the next round is set to be 92, i.e., φ(T+T_{cal}+T_{Null})=92 from which φ can be determined. This also means that 92 RFID tags 14 leave the reader's field at the end of every round. Therefore pᵣ, the average probability of a RFID tag 14 being read in a round, can be expressed as

$$pr = \frac{92}{{G}_{1}} .$$

Having found the lower bound for q and the average value of pᵣ in terms of G₁, it is now possible to re-write Equation 12 as:

$${p}_{r} = \frac{92}{{G}_{1}} = 1 - {( 1 - P )}^{1 / q} \qquad ( 19 )$$

From Equation 19, G₁ can be determined and this completes the design of m-AFSA with EDFSA as the underlying protocol.

It should be noted that for high values of P, it is possible that the value of G₁ obtained from Equation 19 can be less than 177. If so, the frame size of N=256 may no longer be optimal (as per the EDFSA tag grouping rule) for the mobile tag reading system. In this case, the design process is re-started with a smaller frame size of N=128 and continued using the principles outlined above.

### Simulation Results

Described below are the simulation results that delineate the performance of the proposed AFSA framework. The simulations were done in C++ and the results presented here are the outcome of 50 different runs. The variations indicated in the graphs shown in FIG. 4 correspond to the 100% confidence interval. Initially, described is the performance of the AFSA framework in a static setting and then move on to the mobile setting.

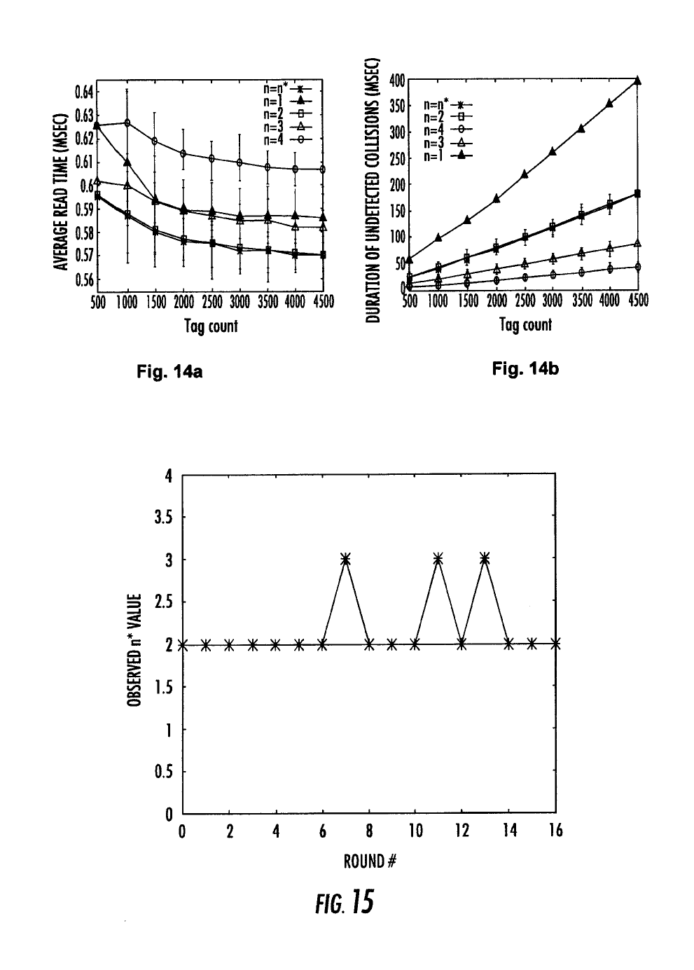

Performance in a Static Setting: To begin with, described is the impact of the parameter n on the performance of the proposed AFSA framework. Discussed is the results that are obtained with EDFSA as the base protocol. Similar results were obtained with DFSA as the base protocol and for the sake of brevity those results are not discussed herein. As mentioned earlier, the parameter n plays an important role in determining the average RFID tag 14 reading time. Larger values of n decrease the number of undetected collisions; however, they increase the duration of the reservation phase and thus may increase the overall round time. Smaller values of n decrease the duration of the reservation phase but increase the number of undetected collisions; thus a n value that is too small can increase the overall round time. This behavior is brought out in the simulation results presented in FIG. 14.

FIGS. 14a and 14b are charts showing simulated AFSA performance with different n values in accordance with the present invention, in particular, FIG. 14a illustrates the average simulated reading time obtained with different n values and FIG. 14b illustrates the average time lost in a round due to undetected collisions for different n values. FIGS. 14a and 14b show that the average RFID tag 14 reading time increases for both small and large n values. We also note that minimizing the time spent in undetected collisions does not necessarily lead to minimum tag reading time. It can be seen that true to its objective, n=n* minimizes the overall tag reading time but not necessarily the time spent in collisions. While n=n* gives the best read time, it is observed that the performance of n=2 is very close to that of n=n*. The reason for this can be found out from the chart shown in FIG. 15. FIG. 15 shows that for most of the (N, K) combinations encountered during the read process, n* is actually 2 and hence the observed behavior. This result also validates to some extent the approximation n*≈2 made above.

Having discussed the performance of AFSA for different n values, we now compare the performance of AFSA with other protocols. The following protocols are compared in our simulation study: (1) DFSA [13]—(Cha et al., 2006), (2) EDFSA [14]—(Lee et al., 2005), (3) ASAP [19]—(Khandelwal et al., 2006), (4) Query Tree (QT) [22]—(Law et al., 2000), (5) Binary Tree (BT) [23]—(Hush et al., 1998), (6) AFSA+DFSA, and (7) AFSA+EDFSA. Note that QT and BT are tree based deterministic tag reading protocols. The protocols are compared in terms of the average tag reading times they achieve and their efficiency. Protocol efficiency is defined as the ratio of time spent in actual tag reading over the total time. We note here that the total time includes several components including actual tag reading time, time spent in collisions, idle time, and protocol overhead (in terms of transmitting reader commands and acknowledgments).

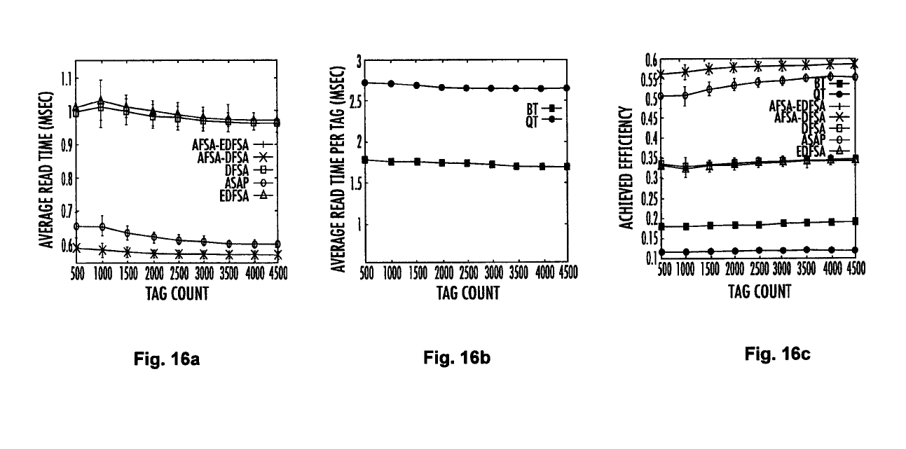

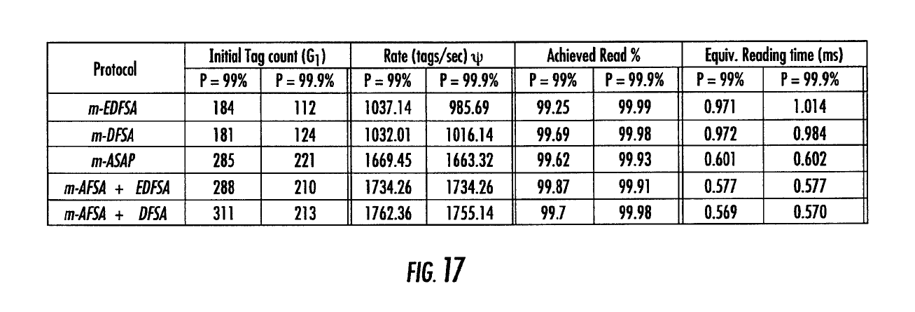

FIGS. 16a-16c are charts showing simulated performance of different tag reading protocols in a static setting, in particular, FIG. 16a illustrates the average tag reading time obtained under ALOHA protocols, FIG. 16b illustrates the average tag reading time obtained under tree based protocols, and FIG. 16c illustrates the efficiency achieved by different protocols. The graphs shown in FIGS. 16a-16c show the performance of different protocols in terms of the aforesaid parameters, wherein the tag reading times of ALOHA based protocols and tree based protocols are shown in separate graphs. In these set of experiments, the AFSA protocols use the optimal n value, i.e., n=n*. From the graphs, it can be seen that all the ALOHA based protocols have smaller average tag reading times than the tree based protocols. Among the two tree based protocols, BT has a better reading time than QT. This is because, in QT, the reader has to transmit the query string in the beginning of each round which consumes bit times. In the case of BT, the reader 12 need not transmit any query string since the tags are assumed to have memory to remember the tree path traversed by them during the reading process. This saves some bit times leading to smaller tag reading times.

Among the ALOHA based protocols, we notice that protocols that utilize the proposed AFSA framework deliver a superior performance in terms of the average tag reading time. AFSA+DFSA and AFSA+EDFSA achieve tag reading times close to 0.57 msec (equivalent to a rate of 1754 tags/sec) while the base protocols' reading times are in the range of 0.97 msec. The reading times achieved under AFSA+EDFSA and AFSA+DFSA are also better than those achieved under the ASAP tag reading protocol. Further, the AFSA protocols achieve the highest efficiency among the seven protocols that are compared. It is also observed that the performance of AFSA+EDFSA and AFSA+DFSA are almost equal to each other. This shows that the proposed AFSA framework is equally good in improving the performance of protocols having limited frame sizes as well as unlimited frame sizes thereby highlighting its applicability to both the classes of ALOHA based tag reading protocols.

Performance in a Mobile Setting: In studying the performance of the AFSA framework in a mobile setting, we use the same system setup found in [19]—(Khandelwal et al., 2006). We set v=5 m/s, lₘₐₓ=2 m, and h=1 m. We studied the system until 50000 RFID tags 14 have been read. Two different target read percentage values of P=99% and P=99.9% are used. The appropriate initial tag count G₁ and the tag departure (and arrival) rate φ are determined as per the discussions given above. The simulation was run for 20 times and the average values are reported. The tables shown in FIG. 17 present the results of the simulation study.

From the results it can be seen that the designed initial tag count allows all the protocols to achieve the desired tag reading percentage. It is also noticed that the tag departure rate under P=99.9% is lower than the departure rate under P=99%. This is due to the fact that in order to meet a higher successful reading rate, contention in the system has to be reduced. Contention can be reduced only by allowing fewer tags to pass through the system. Hence, the lower departure rate for P=99.9%.

Further, it is observed that the proposed AFSA framework significantly improves the system throughput in comparison to the base protocols. This is due to the fact that the protocols under the AFSA framework have a smaller round time which allows them to have more number of tag reading cycles. This in turn allows the protocols to have a higher initial tag count and a higher departure rate without compromising on the target read percentage.

It is also to be noted that when the tag departure rates achieved under the proposed design are translated into tag reading times (by taking the reciprocal of the product of tag departure rate and the achieved read percentage), they are almost equal to the average tag reading times achieved under a static setting. This shows that the proposed mobile system design is close to being the best one can hope for, since the tag reading time achieved for a given protocol under any mobile setting has to be at least the reading time achieved under a static setting.

Tag Requirements for AFSA: Described below, it is shown that the AFSA framework can be implemented on Class I generation I tags and Class 2 generation 2 tags with minimum hardware modification. It is noted that several ALOHA based anti-collision tag reading protocols have already been proposed for Class I Generation I and Class I Generation 2 tags. This implies that such RFID tags 14 currently possess the following abilities: (a) generate a random number within a given range and remember it; (b) identify any particular slot in a frame; (c) transmit the EPC in the chosen slot; and (d) parse through the acknowledgment bit string advertised by the reader 12 and understand the status of their EPC transmissions.

A quick analysis of the different phases in an AFSA round will reveal that in addition to the above capabilities, the RFID tags 14 should possess the following two features in order to implement the proposed framework: (i) ability to transmit a bit sequence other than their EPC—the RFID tags 14 should send n* number of bits in their reservation phase, where n*<<64 (assuming the EPC length to be 64 bits); and (ii) ability to transmit more bits in a round than under existing ALOHA protocols—tags whose reservation was successful in the reservation phase end up transmitting a total of n*+64 bits under AFSA whereas in other ALOHA protocols, they need to transmit only 64 bits.

Feature (i) can be implemented by allowing the tags to transmit the first n* or the last n* bits of their EPCs, and thus eliminate the need for additional memory. While one may argue that n* is a parameter that varies between rounds, as the simulation results have shown, it is possible to approximate n* with 2 and still achieve a good performance. Feature (ii) can be achieved by allowing the reader 12 to induce more energy in the RFID tags 14 by transmitting a stronger electromagnetic pulse. Apparently, one can think that this may result in additional power consumption at the reader 12. However, the improvement achieved in terms of smaller tag reading times may necessitate the reader 12 to be active only for a shorter duration and the resulting energy savings may partially or fully offset the additional energy consumption. Also, in instances where the reader 12 can be recharged periodically from the mains, energy consumption at the reader 12 may not be an issue.

### CONCLUSIONS

Described herein is a framework named Accelerated Frame Slotted ALOHA (AFSA) for reducing the reading time of RFID tags 14 (active or passive) in dense environments. AFSA can be used in conjunction with almost all RFID tag 14 reading protocols that are based on frame slotted ALOHA. Also discussed is the working of AFSA in conjunction with two different ALOHA protocols—one with unlimited frame sizes and the other with limited frame sizes. AFSA reduces the tag reading time by using bitmaps and avoids the wastage in bit times due to collisions and idle slots. Further, also described are extensions of AFSA to read passive tags in a mobile setting. The simulation results showed that AFSA can significantly reduce the average tag reading time with respect to the base protocols and achieve high tag reading rates under both static and mobile settings. The results also show that AFSA works equally well with protocols that use unlimited frame sizes as well as limited frame sizes. Additionally, it is believed that AFSA can be extended by incorporating generic distributions for slot selection.

### REFERENCES

The following references, to the extent that they provide exemplary procedural or other details supplementary to those set forth herein, are specifically incorporated herein by reference.
[1] D. W. Engels and S. E. Sanna, “Standardization requirements within the RFID class structure framework,” tech. rep., Auto-ID Center, January 2005.
[2] S. E. Sarma, “Towards the five-cent tag,” Tech. Rep. MIT-AUTOID-WH-006, Auto-ID Center, 2001.
[3] G. Avoine and P. Oechslin, “RFID traceability: A multilayer problem,” in Financial Cryptography (FC'05), LNCS, Springer, 2005.
[4] Jihoon Myung and Wonjun Lee, “Adaptive Splitting Protocols for RFID Tag Collision Arbitration,” in MOBIHOC 2006, (Florence, Italy), May 2006.
[5] C. Law, K. Lee and K.-Y. Sill, “Efficient memoryless protocol for tag identification,” in Fourth International Workshop on Discrete Algorithms and Methods for Mobile Computing and Communications, (Boston), pp. 75-84, August 2000.
[6] F. Zhou, C. Chen, D. Jin, C. Huang and H. Min, “Evaluation and optimizing power consumption of anti-collision protocols for applications in RFID systems,” in International Symposium on Low Power Electronics and Design, (Newport Beach, Calif.), August 2004.
[7] Vinod Namboodiri and Lixin Gao, “Energy-Aware Tag Anti-Collision Protocols for RFID Systems,” in IEEE PerCom, (White Plains, N.Y.), March 2007.
[8] T. A. Scharfeid, “An analysis of the fundamental constraints on low cost passive radio-frequency identification system design,” Master's thesis, MIT, August 2001.
[9] Jihoon Myung, Wonjun Lee and Jaideep Srivastava, “Adaptive Binary Splitting for Efficient RFID Tag Anti-Collision,” IEEE Communication Letters, vol. 10, pp. 144-146, March 2006.
[10] Jihoon Myung, Wonjun Lee and Timothy K. Shih, “An Adaptive Memoryless Protocol for RFID Tag Collision Arbitration,” IEEE Transactions on Multimedia, vol. 8, pp. 1096-1101, October 2006.
[11] Jihoon Myung and Wonjun Lee, “Adaptive Binary Splitting: A RFID Tag Collision Arbitration Protocol for Tag Identification,” Mobile Networks and Applications (MONET), vol. 11, pp. 711-722, 2006.
[12] H. Vogt, “Multiple object identification with passive RFID tags,” in IEEE International Conference on Systems, Man and Cybernetics (SMC 02), vol. 3, pp. 6-9, October 2002.
[13] J. R. Cha and I. R. Kim, “Dynamic framed slotted ALOHA algorithms using fast tag estimation method for RFID systems,” in third IEEE Consumer Communications and Networking Conference, CCNC, pp. 768-772, 2006.
[14] S. R. Lee, S. D. Joo, and C. W. Lee, “An enhanced dynamic slotted ALOHA algorithm for RFID tag identification,” in Proceedings of the Second International Conference on Mobile and Ubiquitous Systems (MOBIQUITOUS), 2005.
[15] K. Finkenzeller, RFID Handbook: Radio-Frequency Identification Fundamentals and Applications. John Wiley and Sons, 2000.
[16] G. Khandelwal, “Efficient design of dense and time constrained rfid systems,” Master's thesis, Penn State University, August 2005.
[17] Maurizio A. Bonuccelli, Francesca Lonetti, and Francesca Martelli, “Tree Slotted Aloha: a New Protocol for Tag Identification in RFID Networks,” in 2006 International Symposium on a World of Wireless, Mobile and Multimedia Networks (WoWMoM'06), pp. 603-608, 2006.
[18] S. Jain and S. Das, “Collision avoidance in a dense RFID network,” in First international Workshop on Wireless Network Testbeds, Experimental Evaluation and Characterization, September 2006.
[19] G. Khandelwal, A. Yener, K. Lee and S. Serbetli, “ASAP: A MAC Protocol for Dense and Time Constrained RFID Systems,” in ICC International Conference on Communications (ICC), 2006.
[20] “Draft protocol specification for a 900 MHz class 0 radio frequency identification tag,” tech. rep., Auto-ID Center, February 2003.
[21] Murali S. Kodialam and Thyaga Nandagopal, “Fast and reliable estimation schemes in RFID systems,” in MOBICOM 2006, (Los Angeles), pp. 322-333, September 2006.
[22] Ching Law, Kayi Lee, and Kai-Yeung Siu, “Efficient Memoryless Protocol for Tag Identification,” in Fourth International Workshop on Discrete Algorithms and Methods for Mobile Computing and Communications (in conjunction with MOBICOM 2000)” (Boston), August 2000.
[23] D. R. Hush and C. Wood, “Analysis of tree algorithms for RFID arbitration,” in IEEE International Symposium on Information Theory, 1998.

What is claimed is:

1. An RFID reader for reading RFID tags, the RFID reader comprising:
a clock generating clock signals;
a transceiver;
a control unit receiving the clock signals; and
a memory accessible by the control unit and storing computer executable instructions that when executed by the control unit cause the control unit to generate a communication schedule based upon confirmed reservation requests, and to read the RFID tags employing the communication schedule.

2. The RFID reader of claim 1, wherein the memory stores computer executable instructions that when executed by the control unit cause the control unit to transmit an acknowledgement upon reading of the RFID tags.

3. The RFID reader of claim 1, wherein the communication schedule is a stored bit stream that indicates when particular RFID tags will transmit data to the RFID reader.

4. The RFID reader of claim 1, wherein the communication schedule has a plurality of time slots synchronized with the clock signals.

5. An RFID tag, comprising:
transmit/receive circuitry;
a clock;
a control unit;
powering up circuitry including a power source to supply power to the control unit and the transmit/receive circuitry; and
memory storing an electronic product code, and computer executable instructions that when executed by the control unit cause the control unit to:
receive a broadcast during an advertisement phase from a reader via the transmit/receive circuitry, and in response thereto:
synchronize the clock of the RFID tag with a clock of the reader;
generate a reservation request;
transmit the reservation request via the transmit/receive circuitry;
receive a reservation summary including a reserved time to transmit via the transmit/receive circuitry;
transmit the electronic product code at the reserved time via the transmit/receive circuitry; and
receive an acknowledgement from the reader via the transmit/receive circuitry.

6. The RFID tag of claim 5, wherein the memory stores computer executable instructions that when executed by the control unit cause the control unit to generate a random number when generating the reservation request.

7. The RFID tag of claim 5, wherein the power source of the powering up circuitry includes an AC/DC source.

8. The RFID tag of claim 5, wherein the power source of the powering up circuitry utilizes power harvested from RF waves from the reader.

9. A method for fabricating an RFID tag, comprising the steps of:
storing an electronic product code in a memory of the RFID tag;
storing computer executable instructions in the memory of the RFID tag that when executed by a control unit of the RFID tag cause the control unit to:
receive a broadcast during an advertisement phase from a reader via transmit/receive circuitry of the RFID tag, and in response thereto:
synchronize a clock of the RFID tag with a clock of the reader;
generate a reservation request;
transmit the reservation request via the transmit/receive circuitry;
receive a reservation summary including a reserved time to transmit via the transmit/receive circuitry;
transmit the electronic product code at the reserved time via the transmit/receive circuitry; and
receive an acknowledgement from the reader via the transmit/receive circuitry.

10. The method of claim 9, wherein the step of storing the computer executable instructions is performed during the fabrication of hardware forming the memory.

11. The method of claim 9, wherein the computer executable instructions are in the form of software and the step of storing is performed after hardware forming the memory is fabricated.

12. A method for fabricating an RFID reader, comprising the step of:
storing computer executable instructions in a memory of the reader that when executed by a control unit of the reader cause the control unit to generate a communication schedule based upon confirmed reservation requests, and to read the RFID tags employing the communication schedule utilizing a transceiver of the reader.

13. The method of claim 12, wherein the step of storing is performed during the fabrication of hardware forming the memory.

14. The method of claim 12, wherein the computer executable instructions are in the form of software and the step of storing is performed after the hardware forming the memory is fabricated.
